(19) United States
(12) Patent Application Publication
(10) Pub. No.: US 2006/0209970 A1
(43) Pub. Date: Sep. 21, 2006

(54) Adaptive transmission rate communication system

(76) Inventor: Emmanuel Kanterakis, North Brunswick, NJ (US)

Correspondence Address: EMMANUEL KANTERAKIS, 740 HOOVER DRIVE, NORTH BRUNSWICK, NJ, 08902, US

(21) Appl. No.: 11/328,826

(22) Filed: Jan. 10, 2006

Related U.S. Application Data
(60) Provisional application No. 60/642,918, filed on Jan. 11, 2005.

(51) Int. Cl. H04L 27/00; H03M 13/03

(52) U.S. Cl. 375/259; 714/790

(57) ABSTRACT

A method is disclosed by which the data rate of the transmission on a communications link is adjusted according to the underlying channel conditions based on a fast Layer-1 feedback Channel Quality Indicator (CQI) control signal received on the return channel. The method enables the system to transmit a data packet of information at different symbol rates during the transmission of a data packet. Each data packet is transmitted over a number of time slots, with the transmission rate or the modulation scheme used in each time slot is changed dynamically during the transmission of the data packet according to channel quality indicators received from the reverse link.

### RELATED APPLICATIONS

This application is related and claims the benefits of U.S. provisional patent application APPL No. 60/642,918 FILLING DATE Jan. 11, 2005 and entitled “Adaptive transmission rate communication systems”. The content of this provisional application is incorporated herein as reference.

### BACKGROUND OF THE INVENTION

1.0 Technical Field

The present invention related to an improved communication method for use in communication systems employing a variety of communications techniques such as DS-CDMA and OFDMA. The same technique can be used in other communication techniques where, the energy of the transmitted data needs to be kept to a minimum in order to reduce the amount of interference received by other communication systems operating in the same band at the same time.

2.0 Background Art

A method by which the transmission data rate is varying from slot to slot according to channel quality information transmitted on the returned link is disclosed. Currently, variable data rate transmission is achieved by using channel control information (CQI) received on the reverse link about the quality of the forward link. An amount of data is encoded into a fixed time duration frame and transmitted at a fixed data rate, which fixed data rate is adjusted according to the received CQI control data. Therefore, the amount of data that is transmitted per frame varies according to the channel conditions that existed during the previous frame. Though this does present considerable system capacity gains, the update rate of the transmission rate is constrained by the duration of the encoded frame. For example, if the frame duration is 10 msec, the update rate of the data rate is 100 Hz. Lately. Frame durations of 2 msec have been proposed for 3.5-generation cellular systems. This will make the update rate 500 Hz, which can track the channel variations much better that using a 100 Hz update rate. However, reducing the frame duration is not beneficial for various reasons. First, reducing the frame duration reduces the time diversity of the bits in that frame. Reducing diversity amounts to operating in a flat fading channel and therefore, the whole frame is subject to fading. This then requires methods like HARQ in order to gain back some time diversity by either re-transmitting the same data (possibly encoded differently) or by transmitting supplemental coding information at a later time in order to recover previously incorrectly received frames. Second, reducing the frame duration amounts to reducing the size of the transmitted coded packet. It is known that reducing the coded packet size the coding gain is also reduced which in turn reduces the overall system capacity. The method disclosed here circumvents these problems by adapting the transmission rate during the frame transmission thus allowing the frame to be long and still allow the data rate to adjust according to the channel variations.

### SUMMARY OF THE INVENTION

A method is disclosed by which the data rate of the transmission on a communications link is adjusted according to the underlying channel conditions based on a fast Layer-1 feedback Channel Quality Indicator (CQI) control signal received on the return channel. The method enables the system to transmit a data packet of information at different symbol rates during the transmission of a data packet. Each data packet is transmitted over a number of time slots, with the transmission rate or the modulation scheme used in each time slot is changed dynamically during the transmission of the data packet according to channel quality indicators received from the reverse link. The i^{th} data packet is encoded into a single coded frame Fᵢ, which is then transmitted over the link over a Frame Time Interval (FTI) FTIᵢ. This FTIᵢ consists of a number of time-slots, whose number depends on the duration of FTIᵢ. The number of time-slots could vary from one to a maximum number FTI_Slots_Max. A slot-time duration is fixed and equals the update rate of the CQI. The time duration of the i^{th} Frame FTIᵢ cannot be known a-priori and cannot be defined at the onset of its transmission. If the channel conditions are favorable, FTIᵢ is smaller otherwise it is larger. The rate of change of the transmission rate could be many times per FTIᵢ and equals the number of time slots in FTIᵢ. The per time-slot changes in the transmission data rate can be achieved using either or a combination of: variable puncturing rate, variable spreading factor, variable number of symbols transmitted in parallel using multi-codes, variable number of bits/symbol by changing the modulation scheme (i.e., BPSK, QPSK, M-QAM, etc.). For each time-slot transmitted, the transmitter signals the receiver of the nature of the rate change via a Slot_Format_Indicator (SFI). For example, if the CQI signified that the channel is of better quality than before, a higher transmission rate is used over the next time-slot and the SFI indicates that. At the receiver, any or the combined information of the transmitted CQI, the received SFI and the received signal itself is used to determine the per-slot transmission rate used. In case an SFI is not transmitted, the CQI and the received signal can be used. In such a case, the receiver will rely on main part on the information it had itself sent and partly on blind receiver algorithms where the receiver will possibly rely on various hypotheses of transmitted rate combinations over the time slots and choose one whose metric, in some distance sense is closer.

### BRIEF DESCRIPTION OF THE DRAWINGS

FIG. 1 Shows a wireless communications system where a remote station can communicate with the network through the Node-Bs and the Radio Network controllers.

FIG. 2 Shows (a) the timing diagram of the transmission of two frames having four and six time slot durations respectively and (b) the data rate used for the transmission of each time slot of the two frames.

FIG. 3 Shows the data format of the data and signaling/control information for a time slot interval. In the downlink, the signaling/control is time multiplexed with the data information, whereas on the uplink the signaling/control is I/Q multiplexed with the data information.

FIG. 4 Shows the data format of the data and signaling/control information for a time slot interval. The signaling/control is I/Q multiplexed with the data information for both the downlink and uplink.

FIG. 5 Shows the transmitter for variable data rate transmission over different time slots of a variable duration encoded data frame. The signaling/control is I/Q multiplexed with the data.

FIG. 6 Shows the transmitter for variable data rate transmission over different time slots of a variable duration encoded data frame. The data is transmitted using Multicode transmission with the signaling/control transmitted on one of the codes.

FIG. 7 Shows a general block diagram of the receiver for a link utilizing variable data rate transmission over different time slots of a variable duration encoded data frame.

FIG. 8 Shows a table with 16 possible CQI choices of data transmission with different data rates by selecting different parameters for the number of multicodes, modulation used, puncturing rate and processing gain (PG).

### DETAILED DESCRIPTION OF THE PREFERED EMBODIMENT

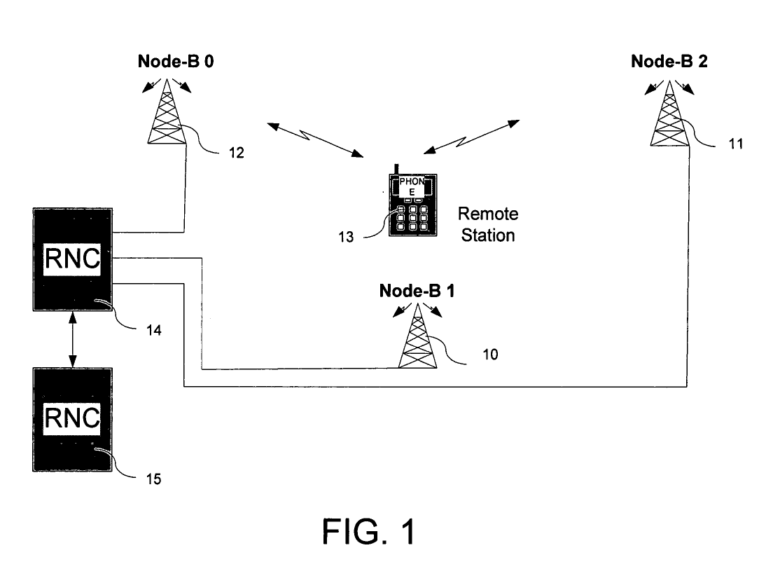

In FIG. 1, an architectural environment over which the Remote Station or User Equipment (UE) 13, the Base Nodes (NodeBs) 10, 11, 12, and Network controllers 14, 15 could be operating is defined. The disclosed method is applicable for any link where the amount of transmitted energy per transmitted bit for a given grade of service needs to be minimized. The architecture depicted in FIG. 1 is normally used in current wireless cellular systems. The UE is connected to one or more NodeBs 10, 11, 12 through a wireless interface. In the disclosed method, the preferred air-interface is that of DS-SS. Other air-interfaces such as those of TDMA, FDMA, OFDM, OFDMA etc are also applicable by varying the transmission rate based on transmission methods applicable to them. Each NodeB is connected to a Radio Network Controller (RNC) and the RNCs are connected together and to other networks like a High Speed Backbone Network. The RNCs provide management, control and transport to NodeBs which in turn manage, control and provide the data transport for the information data to and from the UEs. The specifics on how the overall network operates are beyond the scope of this disclosure and only the optimization of the overall system air-interface capacity is of optimization in this disclosure. The RNCs, provide a set of guidelines for the NodeBs to operate and the NodeBs incorporating these guidelines to system measurements obtained at both the NodeBs and the UEs, try to maximize the overall system capacity while providing the required services to the system users. In cellular networks, a crucial element in the system capacity performance is the amount of energy transmitted over the air for each transmitted bit. Since the transmitted energy acts as interference to all the non-intended receivers within listening range, reducing this transmitted energy will reduce the amount of interference each user is receiving. This in turn will allow the users to operate at either lower average transmit power levels or increase the amount of information that can be transmitted reliably.

The transmitted energy reduction obtained by the proposed method is applicable to both uplink (UE to NodeB) and downlink (NodeB to UE) directions. The ways by which the necessary control signals are generated might be different for the two links, however the basic principle of operation is still the same. In the uplink direction, a NodeB would need to manage the UEs transmitting behavior according to the interference received from the UEs in its own cell, the neighboring cells, the interference received by neighboring NodeBs, and the underlying background noise power. The specific methodology on how these interference components are managed and serve as inputs to the generation of the control signals required is beyond the scope of the disclosed method.

In the downlink direction, the CQI information is transmitted by the UE based on the total channel quality observed at the UE. The UE could be operating in a soft or non-soft handover region. When in a non-soft handover region, the UE transmits the channel quality information for the single NodeB it is connected to; otherwise the downlink channel quality from all NodeBs is transmitted. Additional information such as the downlink loading of neighboring NodeBs could be used as part of the formulation for the data rates a NodeB chooses to transmit to a UE.

For both the uplink and downlink directions, the average and instantaneous throughput for different users often needs to be controlled according to fairness principles and service requirements. In other words, a UE having favorable channel conditions do not necessary have its throughput maximized if that would result in an overall undesirable system fairness profile. The UE will operate at a lower throughput and the unused system capacity will be given to a UE situated at less favorable channel conditions. Service requirements are negotiated on a per UE basis before the UE is provided with the service. Because UEs have different requirements with respect to maximum data rates, average throughput, reliability and delay profiles, system capacity needs to be managed accordingly. Therefore, certain rules need to be incorporated into the operation of the variable data rate transmission methodology being disclosed here for the system to operate within the QoS constraints negotiated by the UEs and imposed by the system. Choosing and operating the rules by which these objectives are achieved is not a trivial task and not within the scope of this disclosure.

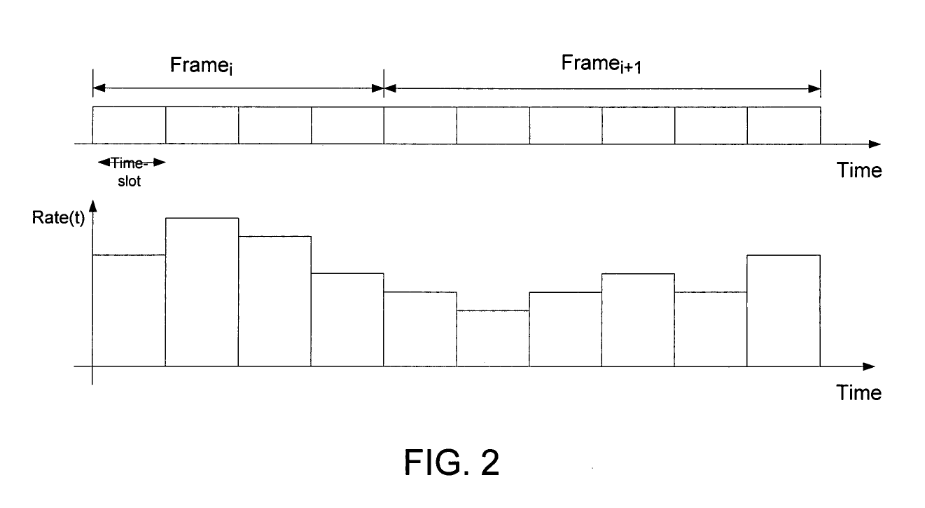

In FIG. 2, the basic principle of the disclosed method is depicted. Here it is assumed that the same amount of data is transmitted with each frame transmission. Each frame consists of a number of slots. The ith frame has time duration of four slots and the (i+1) frame has time duration of six slots. The data rate for each slot is shown in FIG. 2 (b). For the total data transmitted during the two frames to be equal, the integrated data rate over each of the two frame durations need to also be equal. It can be seen that the data rate during the first frame interval is on the average higher than the data rate during the second frame interval. The change in data rate occurs at the time-slot borders and last for the duration of a single time-slot.

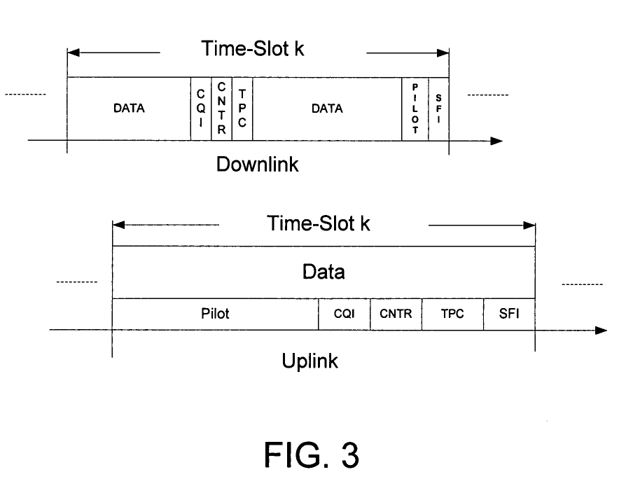

In FIG. 3, an example of time-slot formats is shown for the downlink and uplink physical channels. The exact way the data and control signaling are transmitted is not very important, and here only a single depiction of several different possible choices. For both uplink and downlink, single code physical channels are assumed. On the downlink, the Layer-1 control and signaling data is time-multiplexed with the coded information data. A QPSK or higher level QAM modulation can be used, and the number of symbols per time-slot could be adjusted by selecting one out of number of appropriately predetermined time-slot formats. On the uplink, Layer-1 control and signaling data is either I/Q or time multiplexed with the coded information data. For both the downlink and uplink physical channels, a number of orthogonal codes can be used to transmit multiple information data in parallel. In such a case, the Layer-1 control and signaling data can still be transmitted over a single code while all the remaining codes can be used for information data transmission. In case of Direct-Sequence CDMA (DS-CDMA) systems, varying the processing gain of the transmitted symbols for the duration of a time-slot can be used to vary the transmitted data rate per time-slot.

The Layer-1 control and signaling data is shown to consist of five distinct subsets; the pilot, the Transmit Power Control (TPC), the CQI, the SFI and other Layer-1 control data. The receiver uses the received pilot symbols in order to estimate various channel parameters such as the total received power level, the number of received multipath components and their complex amplitudes needed to demodulate the received data uses the pilot data. These estimated channel parameters along with background noise measurements can be used to form CQI data on both the uplink and downlink. The TPC data is used to control the overall power used to transmit the physical channel. Normally, the TPC data controls the Layer-1 control data power level with the information data power level set in relation to that according to a predetermined table of values. The combination of the received CQI and TPC data in each time-slot control the transmission data rate and transmitted power level during the next time-slot. The SFI data denote the time-slot format used for the following time-slot. A simple way to signify the receiver of the time-slot format to be used in the next time-slot is to provide the change in data rate in relation to the currently used time-slot format. A single +1 or a −1 SFI data bit can be used to signify a data rate change direction. The actual magnitude of the data rate change step could be pre-negotiated at an earlier time. Other possible ways such as multi-bit SFI transmissions are possible for signifying either data rate changes with respect to the previous time-slot or to explicitly denote the transmission data rate level to be used out of a number of possible different transmission data rates. With some additional receiver complexity, the SFI may also easily be used to signify the time-slot format for the same time-slot it is transmitted at. Other Layer-1 control information may be transmitted in each time-slot or selected time-slots. Possible other Layer-1 control data could be receiver power measurements form its own or neighboring NodeBs, time adjustment data in order to time align the paired physical channel with other concurrently received physical channels. Time aligned channels could provide additional channel capacity when they are made to be orthogonal at certain relative channel offsets. Other Layer-1 control information could be, queue loading levels, time delay adjustment for time delay critical applications, data transmission requests, etc.

The methodology by which the data rate is adjusted will be described in steady state on a time-slot by time-slot basis and during initialization of data transmission for both the downlink and uplink physical channels.

On the downlink at each time-slot, the UE receiver receives data from and makes measurements on the received signals from all the NodeBs within listening range or from a specific list of neighboring NodeBs. The data received could specify state variables in the neighboring NodeB that could be used in the UE's decision processes. The measurements normally entail the processing of the received pilot tones form all relevant NodeBs and estimation of their channel profiles. The channel profile of each NodeB constitutes the number of multipath being received, their complex amplitudes and their time offset relative to a local clock reference. From these measurements, short and long-time averages can be derived. For example, Doppler parameters could be estimated, SNRs with respect to the pilot signals from each NodeB, the total average received power, etc. Here, pilot signals could refer to either or both of dedicated pilot signals inserted in a dedicated channel transmitted to the UE or common pilot symbols transmitted to all UEs in the cell. Long-term measurements are being relayed to the primary NodeB in order for the NodeB to make assessments on how to treat the UE on a long-term basis. Short-term measurements, i.e., measurements made on a time-slot basis are used fast link adjustment control. In the method disclosed here, the short time measurements are mostly used to carry out the necessary processes. During a steady state physical channel reception, the UE will perform short-term measurements and estimate the received short term SNR from all NodeB it is connected to. This short term SNR estimates are then used to derive TPC commands, which are sent to the NodeBs. The TPC commands are implicitly controlled by packet error rate performance levels set by the controlling NodeB for the information data received by the UE. The dictated packet error rate performance at the UE requires a certain SNR level to be received by the UE.

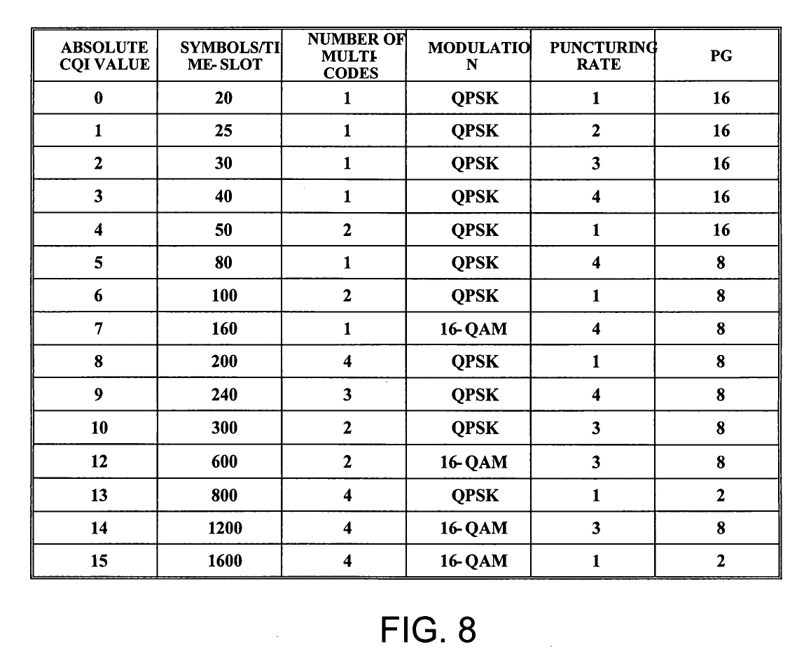

If the packet error level is higher that the one required by the NodeB, the target received SNR is increased, otherwise it is decreased. The TPC commands are normally used to adjust the received control signals and pilot tones to be at a certain SNR level. The power level of the data information is then set in relation to the control signal power level and the current channel data rate. There are various ways to signal adjustments on the transmitted power level. That could be done by sending a simple binary bit signifying a predetermined up or down power step change or by sending more than one bits in order to finely adjust the transmitted power. The power step sizes are semi-static parameters and are set according to the specific mode of transmission used at the time. The received TPC commands at the NodeBs are interpreted and executed according to predefined rules. Normally, a TPC command is explicitly executed on a time-slot by time-slot basis; however, a number of consecutive TPC commands could also be used to form a decision on how to change the transmitted power level to the UE. Having set the channel reference power level (CRPL) to a certain desired level, the received information data rate is adjusted by sending CQI commands. Here, the CQI commands are sent on a time-slot by time-slot basis and are only meant to adjust the received information data rate. The NodeB receiving the CQI commands will adjust various transmission parameters in order to change the transmitted to the UE information data rate. The parameters that can be changed are: the puncturing rate of the transmitted coded frame for that time-slot, the modulation scheme used to transmit the data, i.e., BPSK, QPSK, QAM etc, the number of parallel codes transmitted in parallel (this way of transmitting data in DS-CDMA is normally known as multi-code transmission) and the processing gain used per transmitted symbol (i.e., the number of chips used to spread a symbol in case of DS-SS transmission). Clearly, the list of possible parameters a transmitter can change is large and cannot all be listed here. For example, discontinues transmission, various combinations of different modulation schemes could be used to further increase or decrease the transmission data rate as required. In a non-soft handover case, the ultimate decision on whether the data rate is changed or not could reside at the NodeB. In the soft-handover case, it is not recommended not to follow the rate change requested by the UE. The data rate range over which a UE is allowed to operate in a longer that slot-time or frame-time duration is controlled by the controlling NodeB using a slower signaling mechanism. This signaling could be transmitted in-band along with the transmitted information data or out-of-band thought explicit signaling. For example, the additional Layer-1 control and signaling information could be partly used to transmit such information. The CQI command could consist of a single or multiple bits per time-slot. A single bit would specify a given data rate step change, whereas a multi-bit command would signify either a level change as compared to the one used in the previous time-slot, as compared to a slower changing reference level, or a completely independent static or semi-statically defined data rate level. In this disclosure, the preferred embodiment is to use a single step data rate change from relative to the previous time-slot used level. In case of a multi-bit CQI command, a table signifying the possible date rate changes and the manner by which these changes need to be implemented is used. For example, a table with N entries each entry specifying the various data rate controlling parameters can be used. Assuming the data rate controlling parameters are: Processing Gain (PG) taking values 2, 4, 8, 16, number of multi-codes taking values 1, 2, 3, 4, modulation scheme taking values 1 for BPSK, 2 for QPSK, 3 for 16-QAM, 4 for 64-QAM, and puncturing rates taking values 1, 2, 3, 4, then, 256 possible data rates can be specified by choosing one value from each parameter. An index form 0 to 255 and a single selection option from each of the available data rate parameters could define a table having the full set of choices or a smaller subset. As an example, the table in FIG. 8 could be used. This table is for demonstration of the proposed method only and it might not be the best table to use. Tables need to be tabulated after extensive simulations on the specific environments the system is to operate in. The number of bits per CQI command needs to be traded off with the overhead they present to the system. An explicit transmission of the absolute CQI value used each time-slot using the above table will require the transmission of 4 bits per CQI command. As mentioned before, the number of CQI bits per time-slot could be reduced and the changes referenced to a semi-static or slowly changing base value. For example, if the base CQI value is set to 8 and 2 CQI bits are transmitted denoting a relative rate change of (−1, 0, 1, 2) for (0, 1, 2, 3) being transmitted respectively, a relative CQI value of 0 will signify a transmission based on the absolute CQI value of 7, a relative CQI value of 2 will signify a transmission based on the absolute CQI value of 10. A preferred method of operation is that of using a single CQI bit denoting a single step relative change of the absolute CQI value compared to the one used in the previous slot. That is, if the CQI value in the previous time-slot was 6 and the transmitted CQI bit was a 0 signifying a positive change, the next time-slot will be transmitted according to an absolute CQI value of 7. Likewise, if the CQI value in the previous time-slot was 6 and the transmitted CQI bit was a 1 signifying a negative change, the next time-slot will be transmitted according to an absolute CQI value of 5. Steps larger than one can be used to accommodate fast changing environments. Clearly, many other possible ways of transmitting an absolute CQI value exist.

The Slot Format Indicator (SFI) value is transmitted to signify the Slot Format that is used to transmit the symbols in the current or next time-slot. The choice of which time-slot format the SFI value signifies will depend on how easy it is it is to demodulate Layer-1 control data without knowing the actual time-slot format (i.e., independent Layer-1 control data time-slot format), or whether it could be derived based on choosing the correct format out of a small number of possible formats and have some type of CRC check to verify its correctness. The first choice could be used when the number of symbols per time-slot is small when the use of a CRC will result in a large control overhead and the later choice for a large number of symbols per time-slot. Opting to send the SFI command based on the CQI value used is a possible alternative. Clearly, when relative CQI and SFI values are used to signify the request and time-slot format selection, single transmission errors could propagate throughout the frame or multiple frame transmissions unless a reset of the values occurs at some points and strict checking mechanisms are in place. For example, CRC checks could be easily used for checking correctly received data. Other methods like energy measurement methods could be used to detect possible changes in the number codes being transmitted, a change in the processing gain, etc. A new data indicator (NDI) could be used to signify the start of a new Frame transmission and the resetting of the absolute CQI value if necessary. The NDI could be transmitted as part of the additional Layer-1 control and signaling information and it could be a reserved code sequence transmitted preferably at the last time-slot of the previous frame or the first time slot of the next frame.

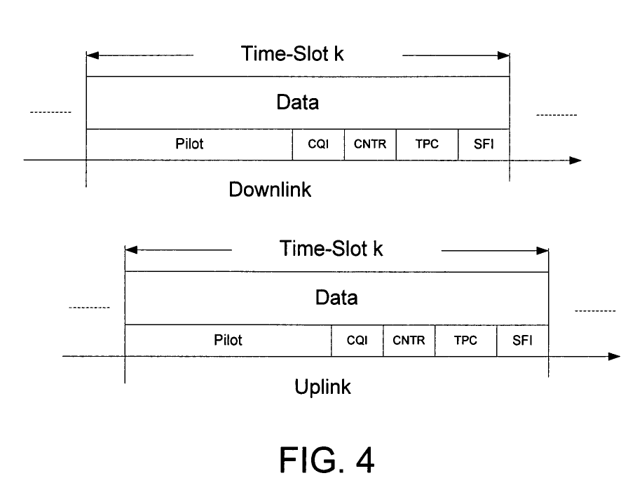

It is often preferable to transmit all the Layer-1 control data on a separate code (i.e., code multiplexed) for both the downlink and uplink channels. FIG. 4 shows a possible time-slot format using the code multiplexing approach. This would allow their transmission at a constant (or semi-static) symbol rate and thus independent of the actual information data transmission. Joint encoding of all the Layer-1 information using error correction coding and CRC protection is also a possibility. Semi-static information could be relayed to the UEs on either their dedicated control channel or via a common channel meant to transmit information to many users in the cell in a Time Division Multiplexed (TDM) fashion.

Since the Frame Transmission Interval (FTI) is variable depending on the channel state during each frame transmission and because there could be a number of parallel codes transmitted in a time-slot, the frame boundaries could fall at the end of a time-slot or at the end of some code within a time-slot. This ambiguity could be resolved by restricting the frames to always end with the completion of a time-slot transmission, or to place an order on the parallel codes used. The parallel codes could be ordered by having a given index and transmitted in a well-defined order.

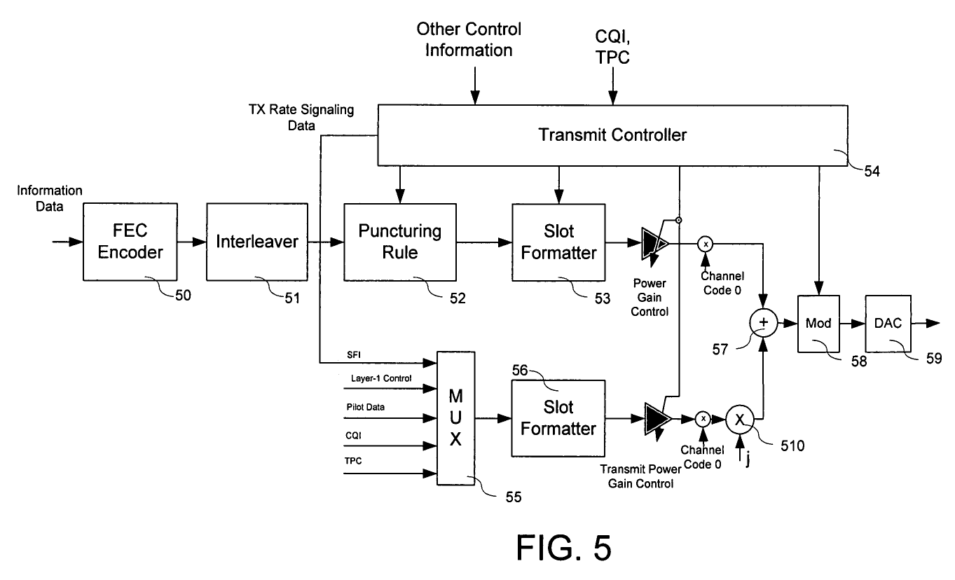

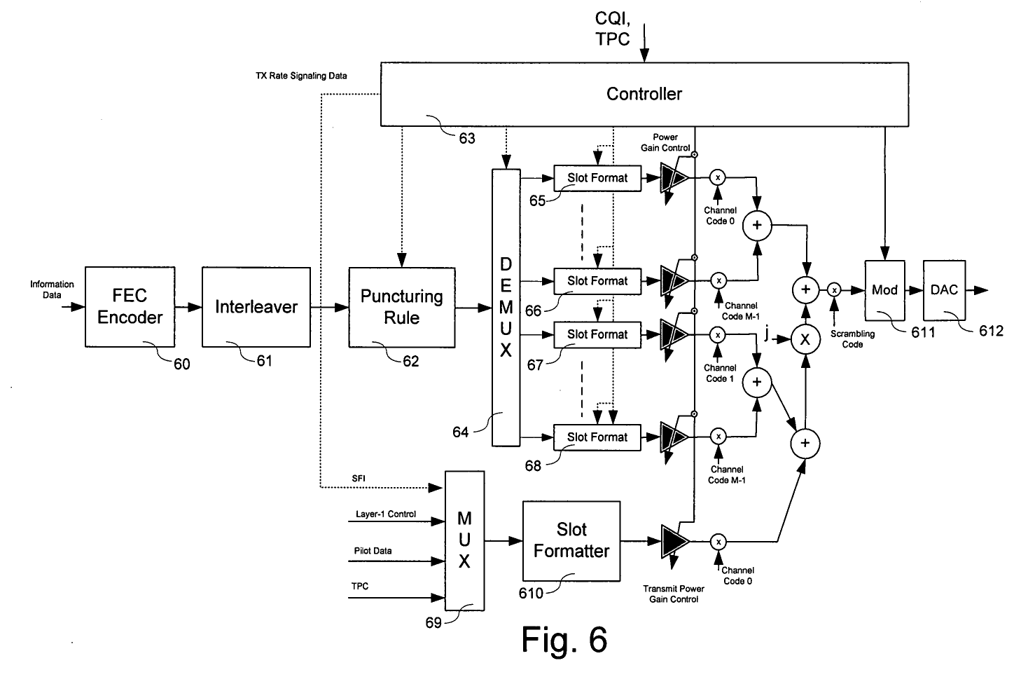

A possible transmitter configuration for the disclosed method is shown in FIG. 5. Here, the information data received from higher system layers is segmented into blocks, which are then encoded into forward error correction (FEC) encoded frames by the FEC encoder 50 and interleaved by the interleaver 51. These encoded frames are then transmitted using the disclosed method. The transmission time of these frames depends on the transmission data rate used throughout the frame transmission. Each frame is stored locally and transmitted using a number of time-slots. For each time slot, a number of encoded symbols are given to the remaining transmitter sections to be further processed and transmitted. The processing applied for each time-slot transmission is depended on the CQI commands received on the paired link and local parameters and measurements. The transmitter controller 54 receives the TPC and CQI commands along with other control information and makes a choice on the time-slot frame format to be used. These frame formats have a one-to-one correspondence with the absolute CQI values. Both the TPC and CQI values are used to determine the transmitted power levels of the Layer-1 control, signaling and information data for each of the many possible used multi-code channels. The CQI values are used to determine the choice of the puncturing rule, the modulation scheme used and the processing gain of the channel code (channelization code) used for each time-slot. The number of encoded symbols used during each time-slot is known once the set of data rate parameters have been configured for that time-slot. Thus, for each time-slot a well defined number of encoded symbols are given to the puncturing block 52 for puncturing. After punctured, the resulting punctured coded segment is used to form a time-slot frame by the use of a slot formatter 53. The symbols in the time-slot frame are adjusted in power, spread by a code having the chosen spreading factor, and first scrambled by a scrambling code and then given to the modulator 58 along with the formatted Layer-1 control information to form modulated symbols for transmission. The modulated symbols are consequently filtered, converted to analog form and transmitted over the air using well-known RF techniques through an antenna. In FIG. 5, the quadrature channel is used to transmit the Layer-1 control and signaling data. That is signified by the multiplication by the complex number j 50. All the Layer-1 control and signaling data are time multiplexed by multiplexer 55 and formatted for each time slot by formatter 56. Error correction coding could be applied and CRC protection could be employed in each time-slot before being transmitted. The resulting time-slot control frame is adjusted in power, spread by the channelization code, scrambled by the scrambling code and then given to the modulator 58 along with the data information to form the modulated symbols. The time multiplexed Layer-1 control and signaling data shown here are: SFI, CQI, Pilot, TPC and other Layer-1 control data. A similar transmitter is shown in FIG. 6, where the use of multi-codes is explicitly shown. Here the punctured, by the puncturing device 62, coded information time-slot block is de-multiplexed by demux 64 to a number of parallel In-phase and Quadrature-phase streams, formatted by slot formatters 65, 66, 67, 68, adjusted in power and spread by a set of orthogonal channelization codes. The channelization codes used in the In-phase channels can be re-used in the Quadrature-phase channels due to the orthogonality of the I and Q streams having being transmitted in quadrature.

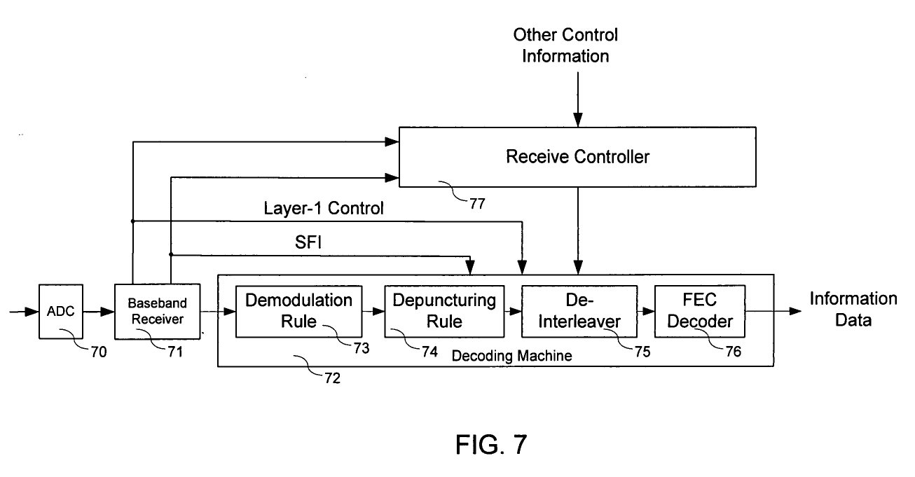

In FIG. 7, the receiver for a link utilizing variable data rate transmission over different time slots over a variable duration encoded data frame. The received signal is first A/D converted by converter 70 and then processed by baseband receiver processor 71. The baseband receiver processor 71 processes the received signals and derives the soft symbol values for de-mapping by the demodulation device 73 and all the necessary signaling information for the slot formats of the received data. The signaling information is given to the receiver processor 71 and decoding machine 72. The decoding machine consists of the demodulator de-mapper 73, the de-puncturing device 74, the de-interleaver 75 and the FEC decoder 76. The decoding machine uses the received data and the signaling information to de-map, de-puncture, de-interleave and decode the received frames. Here, particular signaling arrives for every specific slot which contains information for the frame format used for each current received slot. In general, the structure in FIG. 7, performs the inverse processing performed at the transmitter and shown in FIGS. 5 and 6.

We claim:

1. An improvement to a communications system for transmitting error correction encoded data frames at variable data rates, where the data rate is allowed to change periodically at certain time instances while the encoded data frame is being transmitted according to control signals received during the transmission of the encoded data frame and local to the receiver information, said communications device comprising:
an error correction encoder for encoding a data packet into an encoded data frame;
an interleaver, coupled to the error correction encoder, for interleaving the data in the said encoded data frame, thereby generating an interleaved encoded data frame;
a puncturing device, coupled to said interleaver and transmit controller, for puncturing data segment portions of said interleaved encoded data frame, said data segment portions to be transmitted over a first time slot interval, said puncturing rule based on information input from the transmit controller;
a transmitter for transmitting said data segment portions;
a receiver for receiving information data and control data, said control data used by the puncturing device to generate said puncturing rule.

2. An improvement to a communications system comprising of a transmitter, an error correction encoder, an interleaver, a puncturing device, a transmission controller and a receiver, for transmitting error correction encoded data frames at variable data rates, where the data rate is allowed to change periodically at certain time instances while the encoded data frame is being transmitted according to control signals received during the transmission of the encoded data frame and local to the receiver information, the improvement comprising the steps of:
encoding a packet of un-encoded data into an encoded data frame;
interleaving the data in said encoded data frame, thereby generating an interleaved encoded data frame;
receiving a first control data, said control data used by the transmission controller for generating a first puncturing rule;
puncturing a first data segment portion of said interleaved encoded data frame according to said first puncturing rule, said first data segment portion to be transmitted over a first time slot interval, said first puncturing rule based on information input from the transmit controller;
transmitting first data segment portion;

3. The improvement as set forth in claim 2, further including:
receiving a second control data, said control data used by the transmission controller for generating a second puncturing rule;
puncturing a second data segment portion of said interleaved encoded data frame according to said second puncturing rule, said second data segment portion to be transmitted over a second time slot interval, said second puncturing rule based on information input from the transmit controller;
transmitting second data segment portion;

4. The improvement as set forth in claim 3, further including:
receiving a third control data, said control data used by the transmission controller for generating a third puncturing rule;
puncturing a third data segment portion of said interleaved encoded data frame according to said third puncturing rule, said second data segment portion to be transmitted over a second time slot interval, said third puncturing rule based on information input from the transmit controller;
transmitting third data segment portion;

5. The improvement as set forth in claim 4, further including:
receiving a last segment control data, said last frame segment control data used by the transmission controller for generating a last frame segment puncturing rule;
puncturing a last data segment portion of said interleaved encoded data frame according to said last segment puncturing rule, said a last data segment portion to be transmitted over a last time slot interval, said last segment puncturing rule based on information input from the transmit controller;
transmitting last data segment portion.

6. The improvement as set forth in claim 2, further including:
transmitting according to the same steps additional segment portions until there are no additional data in the interleaved encoded data frame to be transmitted;
transmitting a start of frame indicator (SFI) message, informing the receiver that a new data packet will be transmitted starting at a next time slot interval;

7. The improvement as set forth in claim 1, further including:
a slot formatter, coupled to the puncturing device and the transmit controller, for formatting the punctured encoded data segments into a packet segments of data symbols, said data symbols carrying the information of the punctured encoded data segment;

2. An improvement to a communications system comprising of a transmitter, an error correction encoder, an interleaver, a puncturing device, a transmission controller and a receiver, for transmitting error correction encoded data frames at variable data rates, where the data rate is allowed to change periodically at certain time instances while the encoded data frame is being transmitted according to control signals received during the transmission of the encoded data frame and local to the receiver information, the improvement comprising the steps of:
encoding a packet of un-encoded data into an encoded data frame;
interleaving the data in said encoded data frame, thereby generating an interleaved encoded data frame;
receiving a first control data, said control data used by the transmission controller for generating a first puncturing rule;
puncturing a first data segment portion of said interleaved encoded data frame according to said first puncturing rule, said first data segment portion to be transmitted over a first time slot interval, said first puncturing rule based on information input from the transmit controller;
transmitting first data segment portion;

8. The improvement as set forth in claim 2, further including:
formatting, first data segment portion into a first packet segment of data symbols, said data symbols carrying the information of the punctured encoded data segment in a modulation format that is controlled by the transmission controller;
transmitting first packet segment of data symbols;

9. The improvement as set forth in claim 8, further including:
receiving a second control data, said control data used by the transmission controller for generating a second puncturing rule;
puncturing a second data segment portion of said interleaved encoded data frame according to said second puncturing rule, said second data segment portion to be transmitted over a second time slot interval, said second puncturing rule based on information input from the transmit controller;
formatting, second data segment portion into a second packet segment of data symbols, said data symbols carrying the information of the punctured encoded data segment in a modulation format that is controlled by the transmission controller;
transmitting second packet segment of data symbols;

9. The improvement as set forth in claim 1, further including:
a multiplexer, coupled to the transmission controller, multiplexing a plurality of layer-1 signaling and other control information including any, or any combination of start of frame indicator, layer-1 control, pilot data, channel quality indicator signaling, and transmit power control signaling.

10. The improvement as set forth in claim 7, further including:
a multiplexer, coupled to the transmission controller, multiplexing a plurality of layer-1 signaling and other control information including any, or any combination of start of frame indicator, layer-1 control, pilot data, channel quality indicator signaling, and transmit power control signaling.

11. The improvement as set forth in claim 1, further including:
a de-multiplexer for converting each of the data segment portions output of the puncturing device into a plurality of data segment portions, respectively;
a plurality of slot formatters, coupled to the de-multiplexer, for formatting the plurality of data segment portions into a plurality of packet segments of data symbols, respectively, said data symbols carrying the information of the data segment portions.

12. The improvement as set forth in claim 2, further including:
de-multiplexing first data segment portion output into a plurality of first data segment portions, respectively;
formatting the plurality of first data segment portions into a plurality of first packet segments of first data symbols, respectively, said first data symbols carrying the information of the first data segment portion;
transmitting concurrently the plurality of first packet segments;

13. The improvement as set forth in claim 12, further including:
receiving a second control data, said control data used by the transmission controller for generating a second puncturing rule;
puncturing a second data segment portion of said interleaved encoded data frame according to said second puncturing rule, said second data segment portion to be transmitted over a second time slot interval, said second puncturing rule based on information input from the transmit controller;
de-multiplexing second data segment portion output into a plurality of second data segment portions, respectively;
formatting the plurality of second data segment portions into a plurality of second packet segments of second data symbols, respectively, said second data symbols carrying the information of the second data segment portion;
transmitting concurrently the plurality of second packet segments;

14. An improvement to a communications system for receiving at least one error correction encoded data frame at variable data rates, where the receiving data rate could be different during the reception of different segments of each encoded data frame, control information about the data rate and other signal format attributes of said segments received concurrently with each segment, said communications system comprising:
a baseband processor receiver for processing the received communication signals and providing a decoding device with soft symbol information to be demodulated by a demodulator, the demodulator being a part of the decoding device;
a demodulator, coupled to the baseband processor, for demodulating the soft symbol information and generating soft bit output information, said demodulator receiving control information from said baseband processor and a receiving controller to determine the modulation scheme used on said soft symbol information;
a de-puncturing device, coupled to said demodulator, for de-puncturing said soft bit information generated from said demodulator;
a de-interleaver, coupled to the de-puncturing device for de-interleaving said received error correction encoded data frames, to generate de-interleaved data frames;
a decoder, coupled to said de-interleaver, for decoding said de-interleaved data frames to produce received information data.
